(19) United States
(12) Patent Application Publication
(10) Pub. No.: US 2009/0152661 A1
(43) Pub. Date: Jun. 18, 2009

(54) IMAGE SENSOR AND METHOD FOR MANUFACTURING THE SAME

(76) Inventor: Jea-Hee Kim, Yeoju-gun (KR)

Correspondence Address: SHERR & VAUGHN, PLLC, 620 HERNDON PARKWAY, SUITE 200, HERNDON, VA, 20170, US

(21) Appl. No.: 12/330,603

(22) Filed: Dec. 9, 2008

(30) Foreign Application Priority Data
Dec. 17, 2007 (KR) 10-2007-0132139

(51) Int. Cl. H01L 31/0232; G03F 1/00; G03F 7/20

(52) U.S. Cl. 257/432; 430/5; 430/321; 257/E31.127

(57) ABSTRACT

A method for manufacturing the image sensor includes: forming a photoresist layer on a surface of an image sensor; exposing and developing the photoresist layer using a mask used for fabricating a plurality of micro-lenses, which has a number of first light shielding patterns aligned apart from one another and a number of second light shielding patterns, each being formed at a part, on which four adjacent edges of the first light shielding patterns are centered, so that a photoresist pattern is formed; and reflowing the photoresist pattern to fabricate a plurality of micro-lenses and a concave lens at each part, on which four adjacent edges of the micro-lenses are centered.

The present application claims priority under 35 U.S.C. 119 to Korean Patent Application No. P2007-0132139 (filed on Dec. 17, 2007), which is hereby incorporated by reference in its entirety.

### BACKGROUND

A complementary metal oxide silicon (CMOS) image sensor generally includes a light sensing part to detect light and a logic circuit part to convert the detected light into electrical signals and to provide data from the signals. In order to improve photo sensitivity, a fill factor as a ratio of a light sensing area to the total area of the image sensor is usually increased. Attempts to improve photo sensitivity of the CMOS image sensor have included investigation into light concentration technologies, especially, wherein optical paths of light incident on regions of the sensor other than a light sensing part are altered and concentrated upon the light sensing part.

Among such related technologies, there is a light concentration process that comprises forming a convex lens on a top surface of a light sensing part using a substance with excellent light transmission so as to bend an optical path of incident light, which in turn, increases an amount of light to be delivered to the light sensing part. An image sensor may have as many as several tens of thousands of micro-lenses.

In order to fabricate these micro-lenses, a resist for micro-lenses is first applied to a planarization layer formed on a top surface of a color filter layer and, using a mask for patterning a micro-lens, the resist is partially exposed and developed to form a micro-lens pattern. After that, the micro-lens pattern is subjected to thermal flowing and then baking at high temperature so as to cure the pattern, thereby completing a plurality of micro-lenses. FIGS. 1A and 1B are a plan view and a side view, respectively, of related micro-lenses fabricated at a high temperature. Referring to FIGS. 1A and 1B, because an edge part 5 outlined by four adjacent micro-lenses among these lenses has a gap, the light incident near the edge part 5 is substantially not concentrated and may cause a problem of reducing the performance of a CMOS image sensor.

### SUMMARY

Accordingly, embodiments relate to a method for fabricating a plurality of micro-lenses with improved light concentration, comprising: forming a concave lens at a part, on which four adjacent edges of the micro-lenses are centered, so as to increase a fill factor and improve light concentration of the micro-lenses. Embodiments also relate to an image sensor having a plurality of micro-lenses fabricated by the above method.

Embodiments relate to a mask used for fabricating a micro-lens that includes: a number of first light shielding patterns aligned apart from one another; and a number of second light shielding patterns, each being formed at a part, on which four adjacent edges of the first light shielding patterns are centered, wherein each of the second light shielding patterns has a rectangular shape with an apex consisting of the four adjacent edges of the first light shielding patterns, and a certain light shielding area with a desired line width.

Embodiments relate to a method for manufacturing an image sensor that includes: forming a photoresist layer on a surface of an image sensor; exposing and developing the photoresist layer using a mask used for fabricating a plurality of micro-lenses, which are prepared as described above, so as to form a photoresist pattern; and reflowing the photoresist pattern to fabricate a plurality of micro-lenses and a concave lens at each part, on which four adjacent edges of the micro-lenses are centered.

Embodiments relate to an image sensor that includes: a number of photo-diodes to convert incident light into electrical signals; a number of color filter layers corresponding to the photo-diodes, respectively; a number of micro-lenses corresponding to the color filter layers, respectively; and a number of concave lenses, each being fabricated at a part, on which four adjacent edges of plural micro-lenses are centered.

### DRAWINGS

FIGS. 1A and 1B are a plan view and a side view, respectively illustrating a micro-lenses fabricated.

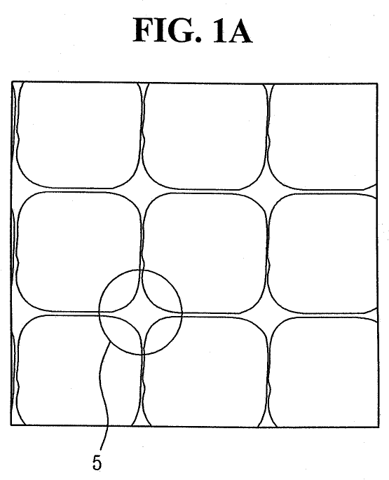

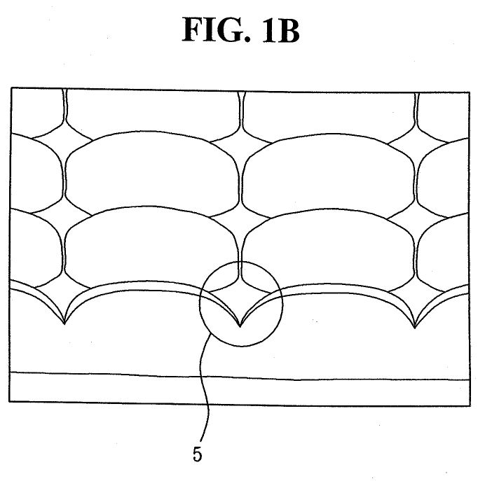

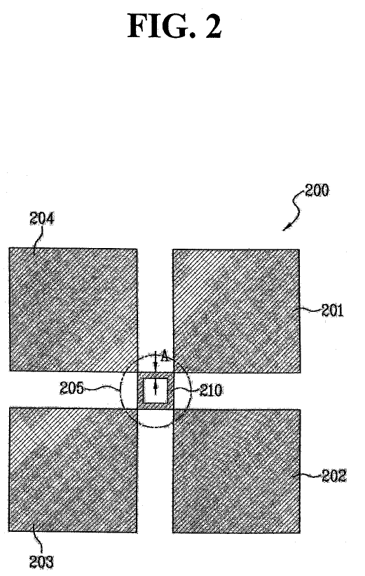

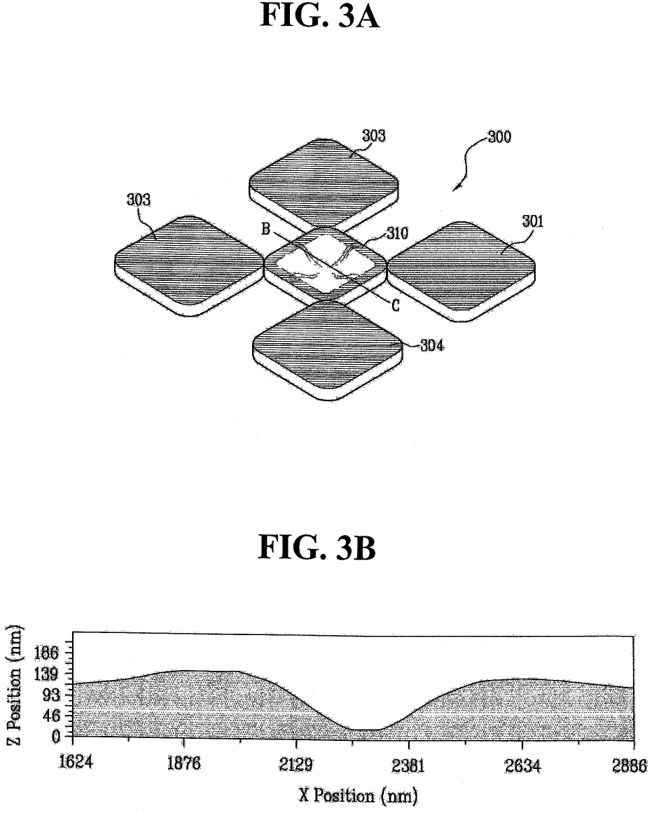

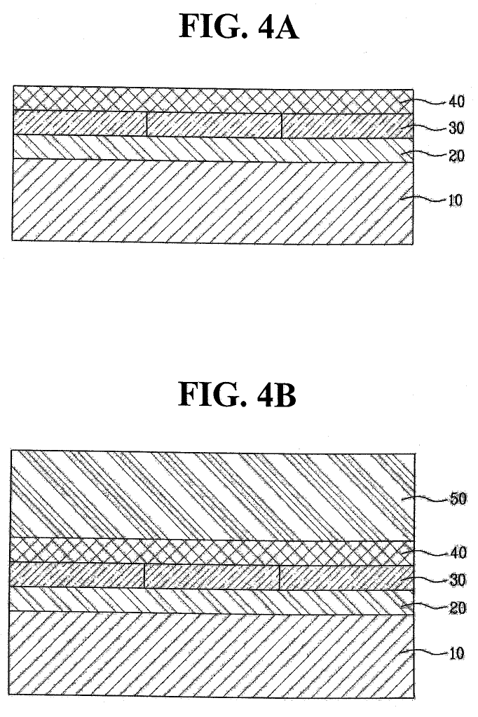

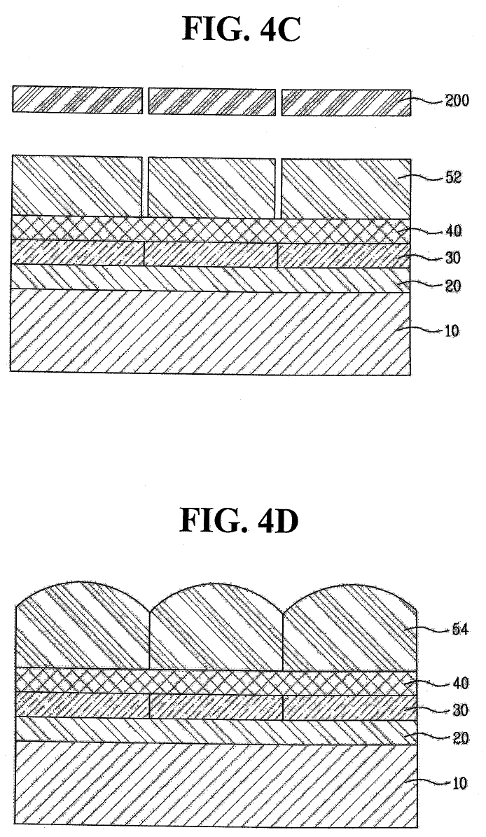

Example FIG. 2 illustrates a mask used for fabricating a micro-lens prepared according to embodiments.

Example FIG. 3A is a perspective view illustrating a micro-lens region that may be formed using the mask shown in example FIG. 2.

Example FIG. 3B is a cross-sectional view illustrating the micro-lens region taken along a line B-C of example FIG. 3A.

Example FIGS. 4A to 4D illustrate a method for manufacturing an image sensor according to embodiments.

### DESCRIPTION

Example FIG. 2 illustrates a mask 200 that may be used for fabricating a micro-lens according to embodiments. Referring to example FIG. 2, the mask 200 may include a number of first light shielding patterns (e.g., 201 to 204) aligned apart from one another, and a number of second light shielding patterns (e.g., 210) each being formed at a location 205 substantially centrally located between where four adjacent edges, or corners, of the first light shielding patterns 201 to 204. Example FIG. 2 illustrates only one set of the first light shielding patterns 201 to 204 adjacent to one another among a number of first light shielding patterns and the one second light shielding pattern 210 associated with these first light shielding patterns. However, embodiments contemplate numerous such sets of similarly arranged and formed first and second light shielding patterns.

As illustrated in example FIG. 2, the first light shielding patterns 201 to 204 may have a rectangular shape and may be aligned and spaced evenly. For example, distance between adjacent patterns may correspond to approximately the line width of an exposure limit resolution. Resolution “R” is typically proportional to the wavelength of an illumination system while being inversely proportional to a lens aperture of the same. More particularly, the resolution may be represented by R=k×λ/NA wherein k is a constant, λ is the wavelength of an illumination system and NA is a lens aperture. For example, if k=0.5, λ is 0.248 and NA is 0.65, the calculated resolution R is 0.19 μm. In this regard, when a microfine pattern having a line width of less than the above resolution (that is, 0.19 μm which refers to “exposure limit resolution”) is applied to a mask, light physically passes through the mask only and does not generate an image on a photoresist.

Accordingly, if the first light shielding patterns 201-204 are aligned spaced at a line width of less than the exposure limit resolution defined as above, spaced pattern images are not formed on a resist for a micro-lens during exposing. As a result, a plurality of micro-lenses may be fabricated in sequence. Also, as illustrated in example FIG. 2, the second light shielding pattern 210 may have a rectangular shape with an apex consisting of four adjacent edges, or corners, of the first light shielding patterns 201 to 204 and a light shielding area with a desired line width A. That is, the second light shielding area 210 may shield light in a region around the rectangular shape up to a certain distance A from its outside edge. The first light shielding patterns 201 to 204 may become a serif.

At a part on which four adjacent edges of plural micro-lenses fabricated in an image sensor are centered, the first light shielding patterns 201 to 204 form a concave lens so as to improve light concentration effects. A size of the concave lens and its light refractive index may be varied depending on the desired light shielding area with the line width A. More particularly, a problem may occur in the micro-lens region according to the light shielding area with the line width A. The line width A may be controlled in a range of, for example, about 30 nm to about 70 nm.

The mask 200 for fabricating the micro-lens shown in FIG. 2 may be embodied as a phase shift mask (PSM). For example, the mask may comprise chromeless PSM, which has no chromium content but does exhibit phase inversion effects of a light transmission layer. Example FIG. 3A is a perspective view illustrating a micro-lens region that may be formed using the mask 200 shown in example FIG. 2. Example FIG. 3B is a cross-sectional view illustrating the micro-lens region taken along a line B-C of example FIG. 3A. Although example FIGS. 3A and 3B illustrate only four adjacent micro-lenses, other lenses are contemplated and may be fabricated in the same way.

Referring to example FIGS. 3A and 3B, a concave lens 310 may be formed at a location substantially centrally located between four adjacent edges, or corners, of the micro-lenses 301 to 304. The concave lens 310 may have a stepped rise as shown in example FIG. 3B. The concave lens 310 may be used to prevent light scattering at the adjacent edge parts of the micro-lenses 301 to 304 and to concentrate the incident light on the same edge parts into photo-diodes. For example, the concave lens 310 may turn the incident light on the adjacent edge parts toward several photo-diodes corresponding to the adjacent micro-lenses 301 to 304, respectively.

Example FIGS. 4A to 4D illustrate a method for manufacturing another image sensor according to embodiments. Referring to example FIG. 4A, an insulating film 20 may be formed on, or over, a semiconductor substrate 10 having a number of photo-diodes and rapid wirings. A plurality of color filter layers 30 corresponding to the photo-diodes may be applied to the insulating film 20, followed by forming a planarization layer 40 on, or over, the color filter layers 30.

Next, as illustrated in example FIG. 4B, a photoresist 50 may be applied on, or over, the planarization layer 40; then, as illustrated in example FIG. 4C, the photoresist 50 may be exposed and developed using the mask 200 to form a photoresist pattern 52. As mentioned above, the mask 200 is useful for fabricating plural micro-lenses as shown in example FIG. 2. As illustrated in example FIG. 4D, the photoresist pattern 52 may be subjected to a continuous reflowing process. For example, the process may include thermally flowing the photoresist pattern 52 at a high temperature then baking to cure the pattern so as to fabricate a plurality of micro-lenses. A thin photoresist part with a thickness of less than the micro-lens which remains after the reflowing process, may protect a gap part during a following oxide etching process and, finally, may leave an oxide fraction on the gap part.

Although not visible in example FIG. 4D, the micro-lens regions formed according to the method illustrated in FIGS. 4A to 4D is shown clearly in example FIG. 2. Thus, the concave lens 310 may be formed using four adjacent micro-lenses.

Referring to FIGS. 3A and 4D, an image sensor according to embodiments includes: a number of photo-diodes to convert incident light into electrical signals; a number of color filter layers 30 corresponding to the photo-diodes, respectively, a number of micro-lenses 52 corresponding to the color filter layers 30, respectively; and a number of concave lenses 210, each being fabricated at a part, on which four adjacent edges of the plural micro-lenses 52 are centered. The image sensor may, for example, be a CMOS image sensor.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A microlens mask comprising:
a plurality of first light shielding patterns aligned apart from one another; and
a second light shielding pattern formed at a location substantially central to a set of adjacent edges of the plurality of first light shielding patterns.

2. The mask of claim 1, wherein the set comprises four adjacent edges.

3. The mask of claim 1, further comprising:
a plurality of second light shielding patterns, each formed at a location substantially central to a respective set of adjacent edges of the plurality of first light shielding patterns.

4. The mask of claim 1, wherein the first light shielding patterns are aligned spaced at a line width of about an exposure limit resolution or less.

5. The mask of claim 1, wherein each of the first light shielding patterns comprises a rectangular shape.

6. The mask of claim 4, wherein the second light shielding pattern comprises a rectangular shape with an apex consisting of four adjacent edges of the plural first light shielding patterns.

7. The mask of claim 6, wherein the second light shielding pattern includes a light shielding area with a line width.

8. The mask of claim 7, wherein the light shielding area comprises a region, having a width of approximately the line width, around a perimeter of the rectangular shape.

9. The mask of claim 7, wherein the line width is in a range between approximately 30 nm to 70 nm.

10. The mask of claim 7, wherein the mask comprises a phase shift mask.

11. A method comprising:
forming a photoresist layer on a surface of an image sensor; and then
exposing and developing the photoresist layer using a mask used for fabricating a plurality of micro-lenses, so as to form a photoresist pattern, wherein the mask includes a plurality of first light shielding patterns aligned apart from one another and a plurality of second light shielding patterns, each being formed at a location substantially central to four adjacent edges of the plurality of first light shielding patterns; and then
reflowing the photoresist pattern to fabricate a plurality of micro-lenses and a concave lens at a part, on which four adjacent edges of the micro-lenses are centered.

12. The method of claim 11, wherein the first light shielding patterns are substantially evenly spaced at a line width of about an exposure limit resolution or less.

13. The method of claim 11, wherein each of the first light shielding patterns comprises a rectangular shape.

14. The method of claim 11, wherein the second light shielding patterns have a rectangular shape with an apex consisting of four adjacent edges of the plural first light shielding patterns.

15. The method of claim 14, wherein each of the second light shielding patterns has a light shielding area with a line width.

16. The method of claim 15, wherein the light shielding area comprises a region, having a width of approximately the line width, around a perimeter of the rectangular shape.

17. The method of claim 15, wherein the line width is between about 30 nm to about 70 nm.

18. The method of claim 15, wherein the mask used for fabricating the micro-lenses comprises a phase shift mask.

19. A device comprising:
a plurality of photo-diodes;
a plurality of color filter layers corresponding to the photo-diodes, respectively;
a plurality of micro-lenses corresponding to the color filter layers, respectively; and
a plurality of concave lenses formed over the microlenses at a location substantially central to adjacent edges of the micro-lenses.

20. The device of claim 19, wherein the device comprises a CMOS image sensor.
